(19) United States
(12) Patent Application Publication
(10) Pub. No.: US 2003/0024566 A1
(43) Pub. Date: Feb. 6, 2003

(54) Combination outdoor portable heating pad and electricity generator

(76) Inventor: Phillip Charles Watts, Longmont, CO (US)

Correspondence Address: Phillip Charles Watts, 269 Wadsworth Circle, Longmont, CO, 80501, US

(21) Appl. No.: 10/196,843

(22) Filed: Jul. 17, 2002

Related U.S. Application Data
(60) Provisional application No. 60/306,274, filed on Jul. 18, 2001.

(51) Int. Cl. H01L 35/00; H01L 37/00

(52) U.S. Cl. 136/200

(57) ABSTRACT

This invention is intended to provide an apparatus that can heat and cool an element consisting of single or multiple elements that can be added conveniently in a portable environment, by generating its own power from the heat of combustion. Surplus power can be exported simultaneously for recharging or operating battery powered equipment such as lights, radios and cell phones or laptop computers. The fact that the unit can provide heat, cooling, electricity, light and can cook or warm foods makes this a portable, man-wearable combination utility device

### BRIEF SUMMARY OF THE INVENTION

A non-tethered portable apparatus enabling instant hot water accessory configurations via quick disconnects. Combination of automatic air separation, liquid pump, and liquid temperature control features in a compact self-powered-chamber by converting the heat of combustion into thermoelectric generated electricity for powering the apparatus and providing external power for portable battery operated equipment such as lights and cell phones and can operate as a portable battery charger for use as an integrated portable unit.

### BRIEF DESCRIPTION OF THE SEVERAL VIEWS OF THE DRAWING

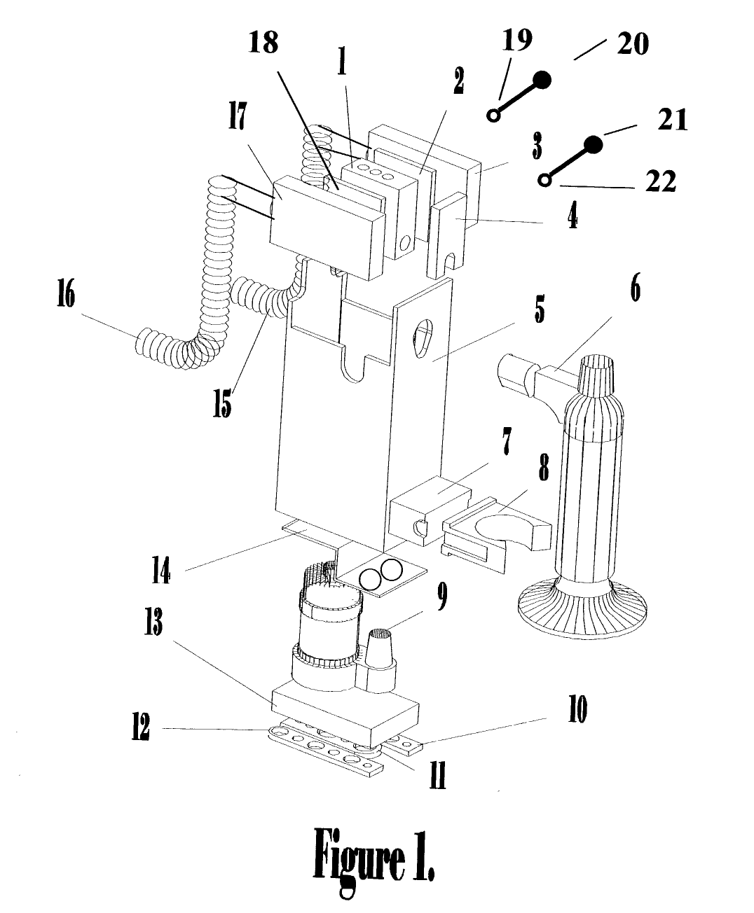

### FIG. 1. Thermoelectric and Hot Water Generator

FIG. 1. depicts an exploded view of the heat and thermoelectric generator and hot water pump contained in an aluminum case that is a water reservoir.

### DETAILED DESCRIPTION OF THE INVENTION

This application pertains to a portable; non-tethered apparatus used in cooling and heating of body pads that could consist of multiple elements configured as a single system. The inherent design allows for the separation of air in the temperature control chamber, which enables pad elements to be added without the need for priming. The method of water-charging newly added components by using the air separation capability of the unit greatly increases ease of use for the apparatus.

Refer to FIG. 1 for the following description. A fluid for circulating to an external pad consisting of concentric loops of tubing. Liquid reservoir is made of the Outer Case, number 5, and the Case Bottom, number 13, and the Case Top number 14. The liquid reservoir is filled via the Pad Return Hose, number 15, by opening the hose and pouring in fluid. This heat transporting fluid is pumped to the pad by the Pump, number 9, and exiting the pump to the Front Cool Block, number 17, and passing through a channel that exits the Front Cool Block and out to the pad element through the Hose Pad Source, number 16. Pad returning fluid is passed through the channel in the Rear Cool Block, number 3, and returns to the fluid reservoir contained by the Outer Case, number 5.

Heat from the Heat Source, number 6, is applied to the Heat Block, number 1. Temperature differential between the sandwich of the Heat Block, number 1, and the Front Cool Block, number 17, and the Rear Cool Block, number 3, generate an electric potential in the Rear Thermoelectric, number 2, and Front Thermoelectric, number 18. The thermoelectric modules are wired to the pump and the external power output jack.

Stability for the apparatus to sit on the ground is accomplished with three pivoting feet, number 10, number 11 and number 12. The heat source is held rigid with the Tank Clip, number 8 and the tank is positioned with the Stand Off, number 7. Heat is contained by the Heat Shield, number 4.

Thermoelectric heating of water in a reservoir is described in U.S. Pat. No. 4,833,888, where the thermoelectric element contacts a stainless steel tank thermally. U.S. Pat. No. 5,072,590 described a chilling system for bottled water where a cold plate is in contact with a reservoir of water. U.S. Pat. No. 4,281,516, described a thermoelectric heat exchanger with a liquid flow path.

Thermal regulation of the circulating fluid is assisted via the aluminum case, number 5 and two screws, numbers 20 and 21, and two o-rings numbers 19 and 22. Course heat content is controlled by the variable valve on the heat source number 6 a self contained torch. Thermal expansion of the screws and o-rings provide a poor heat transfer through the thermoelectrics numbers 18 and 2, and the sandwiched cooling blocks numbers 17 and 3.

Air separation capability of a portable system, number 5, that operates on its own generated electricity, which enables the addition of expansion accessory heating or cooling components consisting of loops of circulating fluid with little effort and can be used to charge batteries is the essence of this invention.

What I claim as my invention is:

1. An integrated generator, number 5, of thermoelectric electricity and hot or cold water circulation system that separates air from the circulation fluid enabling heating and cooling components to be added and primed easily and;

2. A battery charger source using integrated thermoelectrics numbers 18 and 2.;

3. A thermodynamic regulation system that consists of the sandwich of numbers 17,18,1,2,2 that surround the heat source and expand at different rates reducing the heat transfer rate through the sandwich by screws 19 and 21 and o-rings 19 and 22.
